(19) United States
(12) Patent Application Publication
(10) Pub. No.: US 2026/0075787 A1
(43) Pub. Date: Mar. 12, 2026

(54) ELECTROMAGNETIC WAVE SHIELDING SHEET, METHOD FOR MANUFACTURING SAME, AND ELECTRONIC DEVICE COMPRISING SAME

(71) Applicant: AMOGREENTECH CO., LTD., Gimpo-si (KR)

(72) Inventors: Geunyoung JANG, Gimpo-si (KR); Seayoung LIM, Gimpo-si (KR); Hyo-Jung LEE, Gimpo-si (KR); Gyu Min LEE, Gimpo-si (KR); In-Yong SEO, Gimpo-si (KR); Jin Han KIM, Gimpo-si (KR); Kyung Su KIM, Gimpo-si (KR)

(73) Assignee: AMOGREENTECH CO., LTD., Gimpo-si (KR)

(21) Appl. No.: 19/107,597

(22) PCT Filed: Sep. 1, 2023
(86) PCT No.: PCT/KR2023/013099

§ 371 Date: Feb. 28, 2025

(30) Foreign Application Priority Data
Sep. 2, 2022 (KR) 10-2022-0111262

(51) Int. Cl. H05K 9/00

(52) U.S. Cl. CPC H05K 9/009; H05K 9/0088

(57) ABSTRACT

Provided is a method for manufacturing an electromagnetic wave shielding sheet. The electromagnetic wave shielding sheet has excellent vertical shielding performance, prevents the lateral leakage of electromagnetic waves, has a good close contact even with a curved or stepped surface to be attached due to the excellent flexibility thereof, and has excellent compression characteristics, and therefore, it may be possible to realize an electromagnetic wave shielding sheet that can be used in various mounting areas that may have thickness tolerances.

### CROSS-REFERENCE TO THE RELATED APPLICATIONS

This application is the national phase entry of International Application No. PCT/KR2023/013099, filed on Sep. 1, 2023, which is based upon and claims priority to Korean Patent Application No. 10-2022-0111262, filed on Sep. 2, 2022, the entire contents of which are incorporated herein by reference.

### TECHNICAL FIELD

The present invention relates to an electromagnetic wave shielding sheet, a method of manufacturing the same, and an electronic device comprising the same.

### BACKGROUND

Electromagnetic waves refer to a phenomenon in which energy moves in the form of a sinusoidal wave as electric and magnetic fields interact with each other and are useful in electronic devices such as wireless communication and radar. While the electric field is generated by a voltage and has characteristics of being easily shielded by an increase of a distance or by obstacles such as trees, the magnetic field is generated by a current and has characteristics of being inversely proportional to a distance, but not being easily shielded.

Meanwhile, recent electronic devices are sensitive to electromagnetic interference (EMI) generated by internal or external interference sources within the electronic devices, and there is a concern in that malfunctions of the electronic devices may be caused by electromagnetic waves. In addition, users of the electronic devices may also be affected by the electromagnetic waves generated by the electronic devices.

Thus, interest in electromagnetic wave shielding materials for protecting components of electronic devices or the human body from electromagnetic wave sources or externally radiated electromagnetic waves has increased rapidly.

The electromagnetic wave shielding material is typically manufactured from a conductive material, and electromagnetic waves emitted toward the electromagnetic wave shielding material are reflected by the electromagnetic wave shielding material or flow to the ground, thereby shielding the electromagnetic waves. Meanwhile, an example of the electromagnetic wave shielding material may be a metal case or a metal plate. However, the electromagnetic wave shielding material has difficulty in exhibiting flexibility and stretchability and is not easily deformed/restored into various shapes after being manufactured once, and therefore there is a problem that it is difficult to employ the electromagnetic wave shielding material in various applications. In particular, it is difficult for the electromagnetic wave shielding material such as a metal plate to be in close contact with components that require protection from components or sources generating electromagnetic waves without spacing, and cracks may occur due to bending in portions with step differences or irregularities, which causes difficulty in fully exhibiting electromagnetic wave shielding performance.

In order to solve these problems, there have been increasing attempts recently to secure flexibility together with electromagnetic wave shielding performance by imparting conductivity to a substrate in the form of a fiber web.

However, even when flexibility is secured, it is not easy for the electromagnetic wave shielding member in the form of a fiber web to reach a required level of electromagnetic wave shielding performance.

In addition, when plating is performed by increasing a thickness and a density of a fiber web in order to improve electromagnetic wave shielding performance, a metal layer with a predetermined thickness may be formed on a fiber from an outer surface portion of the fiber web in contact with a plating solution and an outer surface portion thereof. However, the metal layer is not formed on a fiber located in a central portion of the fiber web where it is difficult for the plating solution to infiltrate, and thus it may be difficult to exhibit sufficient vertical electromagnetic wave shielding performance. In addition, there is a concern that electromagnetic waves may propagate to sides through the central portion where the metal layer is not formed, and thus it will be difficult to secure sufficient electromagnetic wave shielding performance in any case.

### SUMMARY

### Technical Problem

The present invention is directed to solving the above-described problems and providing an electromagnetic wave shielding sheet that can protect a user and prevent malfunction of other components within a device or other adjacent devices by having high-performance vertical shielding performance, preventing lateral leakage of electromagnetic waves, and blocking external emission of the electromagnetic waves generated from an electromagnetic wave generation source, a method for manufacturing the same, and an electronic device including the same.

The present invention is also directed to providing an electromagnetic wave shielding sheet that can be used in various mounting areas with thickness tolerances by having excellent flexibility to achieve good adhesion to curved or stepped adhesive surfaces and having excellent compression characteristics, a method of manufacturing the same, and an electronic device including the same.

### Technical Solution

One aspect of the present invention to solve the above-described problems provides a method of manufacturing an electromagnetic wave shielding sheet, which includes operation (1) of manufacturing an electromagnetic wave shielding part having a thickness ranging from 100 μm to 300 μm by electroless plating a fiber web layer in which a first fiber web, a second fiber web, and a third fiber web satisfying a relational expression (a) d₂<d₃≤d₁ (wherein d₁, d₂, and d₃ are densities of the first fiber web, the second fiber web, and the third fiber web, respectively) are sequentially laminated, and operation (2) of laminating a first conductive adhesive member on one surface of the electroless-plated first fiber web of the electromagnetic wave shielding part and laminating a second member on one surface of the electroless-plated third fiber web of the electromagnetic wave shielding part.

According to one embodiment of the present invention, the second fiber web may include a bicomponent fiber having a low melting point component, and the fiber web layer may be manufactured by attaching one of the first fiber web and the third fiber web to one surface of the second fiber web through heat and then attaching the other to the other surface of the second fiber web through heat.

In addition, the first fiber web, the second fiber web, and the third fiber web may be formed of a first fiber, a second fiber, and a third fiber, respectively, and a diameter of the second fiber may be greater than that of each of the first fiber and the third fiber.

In addition, a density of the first fiber web may range from 0.6 g/m³ to 2.0 g/m³, and a density of the third fiber web may be 0.6 g/m³ or more.

In addition, a ratio of the sum of thicknesses of the first fiber web and the third fiber web to a thickness of the second fiber web may range from 1:1.5 to 1:10.

In addition, the first fiber web, the second fiber web, and the third fiber web may satisfy relational expressions (b) to (d) according to the following conditions:
the relational expression (b) is a₁≤a₃<a₂, wherein a₁, a₂, and a₃ are porosities of the first fiber web, the second fiber web, and the third fiber web, respectively, the relational expression (c) is b₁≤b₃<b₂, wherein b₁, b₂, and b₃ are mean pore diameters of the first fiber web, the second fiber web, and the third fiber web, respectively, and the relational expression (d) is c₃≤c₁<c₂, wherein c₁, c₂, and c₃ are basis weights of the first fiber web, the second fiber web, and the third fiber web, respectively.

In addition, the fiber web layer may further include a fourth fiber web having a density that is less than or equal to that of the second fiber web between the first fiber web and the second fiber web. In this case, each of the second fiber web and the fourth fiber web may include a bicomponent fiber containing a low melting point component, and the fiber web layer may be manufactured by attaching the first fiber web to one surface of the fourth fiber web through heat, attaching the third fiber web to one surface of the second fiber web through heat, and then attaching the second fiber web and the fourth fiber web through heat.

In addition, the first fiber web and the fourth fiber web may be formed of the first fiber and the fourth fiber, respectively, and a diameter of the fourth fiber may be greater than that of the first fiber.

In addition, the first fiber web, the second fiber web, and the third fiber web may satisfy relational expressions (e) to (g) according to the following conditions:
the relational expression (e) is a₁≤a₃<a₂≤a₄, wherein a₁, a₂, a₃, and a₄ are porosities of the first fiber web, the second fiber web, the third fiber web, and the fourth fiber web, respectively, the relational expression (f) is b₁≤b₃<b₂≤b₄, wherein b₁, b₂, b₃, and b₄ are mean pore diameters of the first fiber web, the second fiber web, the third fiber web, and the fourth fiber web, respectively, and the relational expression (g) is c₃≤c₁<c₄≤c₂, wherein c₁, c₂, c₃, and c₄ are basis weights of the first fiber web, the second fiber web, the third fiber web, and the fourth fiber web, respectively.

Another aspect of the present invention provides an electromagnetic wave shielding sheet including an electromagnetic wave shielding part which is formed of a metal-coated fiber in which a metal layer surrounds a fiber, in which the metal layer has a web shape of a three-dimensional network structure integrally formed in an entire region in a thickness direction, in which a first web part, a second web part, and a third web part satisfying a relational expression (A) D₂<D₃≤D₁ (wherein D₁, D₂, and D₃ are densities of the first web part, the second web part, and the third web part, respectively) are sequentially included in the thickness direction, and which has a thickness ranging from 100 μm to 300 μm; a first conductive adhesive member disposed on one surface of the first web part of the electromagnetic wave shielding part; and a second member disposed on one surface of the third web part of the electromagnetic wave shielding part.

According to one embodiment of the present invention, a thickness of the microporous layer may range from 0.1 μm to 2 μm.

In addition, the metal layer may be formed of one or more metal materials selected from the group consisting of aluminum, nickel, copper, silver, gold, chromium, platinum, a titanium alloy, and stainless steel.

In addition, the metal-coated fiber in the second web part may have a larger diameter than the metal-coated fibers located in the first web part and the third web part.

In addition, the electromagnetic wave shielding part may further include a fourth web part in which a metal-coated fiber having a larger diameter than the metal-coated fibers located in the first web part and the second web part is disposed between the first web part and the second web part.

In addition, the first conductive adhesive member may contain an adhesive component and conductive fillers dispersed in the adhesive component and occupying 5 to 20 wt % based on the total weight of the first conductive adhesive member.

In addition, the second member may be an adhesive member, a second conductive adhesive member, or a cover member.

In addition, the second member may be the second conductive adhesive member, and the second conductive adhesive member may have adhesive strength of 20% or less of an adhesive strength of the first conductive adhesive member measured according to KS T 1028.

In addition, the second member may be the cover member, and the cover member may include a protective film and an adhesive layer formed on one surface of the protective film.

In addition, still another aspect of the present invention provides an electronic device including the electromagnetic wave shielding sheet according to the present invention.

### Advantageous Effects

An electromagnetic wave shielding sheet according to the present invention can have excellent vertical shielding performance, prevent lateral leakage of electromagnetic waves, and block external emission of the electromagnetic waves generated from an electromagnetic wave source, thereby protecting a user and preventing malfunction of other parts within a device or other adjacent devices. In addition, the electromagnetic wave shielding sheet can be used in various mounting areas with thickness tolerances by having excellent flexibility to achieve good adhesion to curved or stepped adhesive surfaces and having excellent compression characteristics.

### BRIEF DESCRIPTION OF THE DRAWINGS

FIGS. 1 and 2 are cross-sectional views and partially enlarged views illustrating fiber web layers manufactured during a process of manufacturing an electromagnetic wave shielding sheet according to various embodiments of the present invention.

FIG. 3 is a cross-sectional view illustrating an electromagnetic wave shielding sheet according to one embodiment of the present invention.

FIGS. 4A and 4B are cross-sectional views illustrating metal-coated fibers provided in an electromagnetic wave shielding part of the electromagnetic wave shielding sheet according to one embodiment of the present invention, wherein FIG. 4A is a cross-sectional view illustrating a metal-coated fiber located in a first web part and a third web part, and FIG. 4B is a cross-sectional view illustrating a metal-coated fiber located in a second web part.

FIGS. 5A and 5B are several examples illustrating a second member included in the electromagnetic wave shielding sheet according to one embodiment of the present invention, wherein FIG. 5A is a cross-sectional view illustrating a second conductive adhesive member, and FIG. 5B is a cross-sectional view illustrating a cover member.

### DETAILED DESCRIPTION OF THE EMBODIMENTS

Hereinafter, embodiments of the present invention will be fully described in detail, which is suitable for easy implementation by those skilled in the art to which the present invention pertains with reference to the accompanying drawings. The present invention may be implemented in various different forms, and thus it is not limited to embodiments which will be described herein. In the drawings, some portions not related to the description will be omitted in order to clearly describe the present invention, and the same or similar reference numerals are given to the same or similar components throughout this disclosure.

An electromagnetic wave shielding sheet according to one embodiment of the present invention may be manufactured by operation (1) of manufacturing an electromagnetic wave shielding part having a thickness of 100 μm or more by electroless-plating a fiber web layer in which a first fiber web, a second fiber web, and a third fiber web are sequentially stacked, and operation (2) of laminating a first conductive adhesive member on one surface of the electroless-plated first fiber web of the electromagnetic wave shielding part and laminating a second member on one surface of the electroless-plated third fiber web of the electromagnetic wave shielding part.

First, operation (1) according to the present invention is an operation of manufacturing the electromagnetic wave shielding part having a thickness of 100 μm or more, and the electromagnetic wave shielding part is manufactured by electroless plating the fiber web layer in which the first fiber web, the second fiber web, and the third fiber web are sequentially laminated and which satisfies a relational expression (a) d₂<d₃≤d₁ (wherein d₁, d₂, and d₃ are densities of the first fiber web, the second fiber web, and the third fiber web, respectively).

Recently, the use of an electroless plating technology for a fiber web has been increasing. However, in the case of a fiber web with a density sufficient to exhibit electromagnetic wave shielding performance, there is a problem that when a thickness exceeds a predetermined thickness, the plating solution does not sufficiently infiltrate into the central portion of the fiber web, making it difficult for a metal layer to be formed on a fiber located in the central portion of the fiber web. In particular, when the density of the fiber web is further increased in order to implement high-performance electromagnetic shielding performance, an allowable plating thickness that can be plated on the central portion of the fiber web is greatly reduced, and a fiber web with a high density and a high thickness is very difficult to plate on the fiber located in the central portion in a thickness direction.

In order to solve this problem, a method of implementing an electromagnetic wave shielding part by electroless-plating each of several fiber webs with thin thicknesses and high densities to reach a target thickness and then stacking them may be considered. In this case, a separate adhesive is required to attach the electroless-plated fiber webs to each other, and when the separate adhesive is interposed between the plated fiber webs, there is concern that it will be difficult to exhibit sufficient electromagnetic wave shielding performance because electromagnetic waves leak through the adhesive with no electrical conductivity, and the adhesive may block pores of the plated fiber webs, thereby reducing flexibility.

While continuously conducting research in order to solve these problems, the inventors of the present invention have implemented an electromagnetic wave shielding part in which a metal layer is integrally formed on fibers constituting a fiber web by performing electroless plating on the fiber web having a target thickness and formed even on the fibers located in a central portion of a thick fiber web by laminating several fiber webs having different densities and performing electroless plating on the laminated fiber web having a target total thickness.

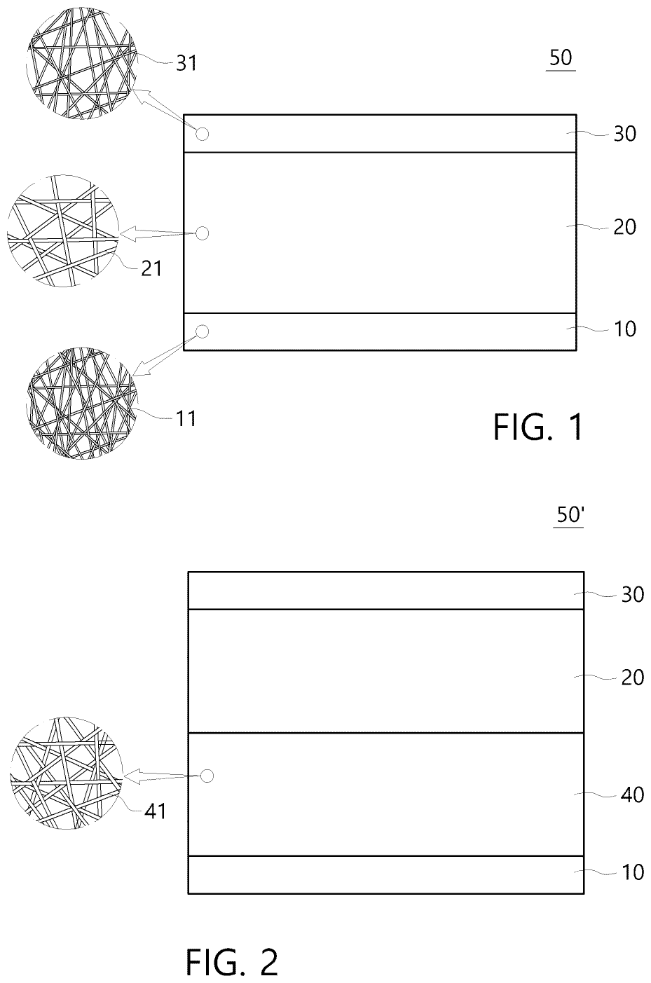

First, as shown in FIG. 1, in order to implement an electromagnetic wave shielding part having a thickness of 100 μm or more, preferably, ranging from 100 μm to 300 μm, a first fiber web 10, a second fiber web 20, and a third fiber web 30 are sequentially stacked to manufacture a fiber web layer 50. The first fiber web 10, the second fiber web 20, and the third fiber web 30 are formed to satisfy a relational expression (a) d₂<d₃≤d₁ (wherein d₁, d₂, and d₃ are densities of the first fiber web, the second fiber web, and the third fiber web, respectively), and since the plating is smoothly formed on the central portion in a thickness direction with a sufficient thickness, leakage of electromagnetic waves is prevented, and since a surface has a high density, it can be advantageous in exhibiting further improved electromagnetic wave shielding performance.

Specifically, the first fiber web 10 and third fiber web 30 are layers for vertical electromagnetic wave shielding after the plating and are implemented with higher densities than the second fiber web 20. In this case, the density of the third fiber web 30 may be implemented to be less than or equal to the density of the first fiber web 10. When both the first fiber web 10 and the third fiber web 30 are implemented with high densities and the density of the third fiber web 30 is implemented with a lower density than the first fiber web 10, it may be advantageous for forming a flow in which a plating solution flows into the fiber web layer 50 through the third fiber web 30 during the electroless plating process. In addition, when the density of the third fiber web 30 is implemented as a high density at the same level as that of the first fiber web 10, there is an advantage of being able to further improve shielding performance for electromagnetic waves incident on both sides of the electromagnetic wave shielding part.

In addition, the second fiber web 20, which is implemented with a relatively lower density than the first fiber web 10 and the third fiber web 30, may increase the overall thickness of the electromagnetic wave shielding part and exhibit sufficient compressive characteristics when the electromagnetic wave shielding sheet is disposed in an attachment portion where a thickness tolerance is present. In addition, the low density of the second fiber web 20 may help the flow of the plating solution formed from the third fiber web 30 reach a central portion of the fiber web layer 50, thereby improving the plating property of fibers located in the central portion. In addition, since the plating solution reaching the central portion may move quickly to the first fiber web 10 again, the plating process may be completed in a shorter time and with excellent quality even when the density of the first fiber web 10 is significantly high.

Meanwhile, when the density of the second fiber web 20 is increased to a level similar to that of the third fiber web 30, it may be advantageous in further improving the electromagnetic wave shielding performance.

Specifically describing the first fiber web 10 and the third fiber web 30, in order to exhibit vertical electromagnetic wave shielding performance, the third fiber web 30 may be implemented with a density of 0.6 g/cm³ or more, or as another example, ranging from 0.6 g/cm³ to 2 g/cm³ or 0.6 g/cm³ to 1 g/cm³, and in order to exhibit high electromagnetic wave shielding performance, the first fiber web may be implemented with a density ranging from 0.6 g/cm³ to 1 g/cm³. In addition, for the high electromagnetic wave shielding performance, a first fiber 11 forming the first fiber web 10 and a third fiber 31 forming the third fiber web may each independently have a diameter of 15 μm or less, more preferably, ranging from 5 μm to 10 μm. In addition, in order to improve the electromagnetic wave shielding performance and electroless plating processability, the first fiber web 10 may have a basis weight ranging from 6 g/m² to 18 g/m², more preferably, 8 g/m² to 15 g/m², a thickness ranging from 12 μm to 20 μm, more preferably, 14 μm to 18 μm, a porosity ranging from 30% to 70%, more preferably, 40% to 60%, and a mean pore diameter ranging from 2 μm to 15 μm, more preferably, 5 μm to 10 μm. In addition, the third fiber web 30 may have a basis weight ranging from 6 g/m² to 18 g/m², more preferably, 8 g/m² to 15 g/m², a thickness ranging from 12 μm to 20 μm, more preferably, 14 μm to 18 μm, a porosity ranging from 30% to 70%, more preferably, 40% to 60%, and a mean pore diameter ranging from 2 μm to 15 μm, more preferably, 5 μm to 10 μm.

In addition, known materials that can be implemented as fibers may be used as the first fiber 11 and the third fiber 31 without limitation, and examples thereof may include one or more selected from the group consisting of polyurethane, polystyrene, polyvinyl alcohol, polymethyl methacrylate, polylactic acid, polyethyleneoxide, polyvinyl acetate, polyacrylic acid, polycaprolactone, polyacrylonitrile, polyvinylpyrrolidone, polyvinylchloride, polycarbonate, polyetherimide, polyethersulphone, polybenzimidazol, polyamide, polyethylene terephthalate, polybutylene terephthalate, and a fluorine-based compound. In addition, the fluorine-based compound may include one or more compounds selected from the group consisting of polytetrafluoroethylene (PTFE)-based, tetrafluoroethylene-perfluoroalkyl vinyl ether copolymer (PFA)-based, tetrafluoroethylene-hexafluoropropylene copolymer (FEP)-based, tetrafluoroethylene-hexafluoropropylene-perfluoroalkyl vinyl ether copolymer (EPE)-based, tetrafluoroethylene-ethylene copolymer (ETFE)-based, polychlorotrifluoroethylene (PCTFE)-based, chlorotrifluoroethylene-ethylene copolymer (ECTFE)-based, and polyvinylidene fluoride (PVDF)-based compounds. As a more specific example, each of the first fiber 11 and the third fiber 31 may be polyethylene terephthalate.

In addition, the first fiber web 10 and the third fiber web 30 may be manufactured through a known method of forming a fiber web, and as an example, the first fiber web 10 and the third fiber web 30 may be dry nonwoven fabrics including chemical bonding nonwoven fabrics, thermal bonding nonwoven fabrics, and airlay nonwoven fabrics, wet nonwoven fabrics, spanless nonwoven fabrics, or needle-punched nonwoven fabrics and may be manufactured through a known nonwoven fabric manufacturing method such as being melt blown or through a calendering process for a fiber mat formed by accumulating fibers spun through electrospinning, and as an example, the first fiber web 10 and the third fiber web 30 may be wet nonwoven fabrics manufactured through a wet-laid method.

In addition, in order to increase the overall thickness of the electromagnetic wave shielding part, exhibit sufficient compressive characteristics when the electromagnetic wave shielding sheet is disposed on an attachment portion where a thickness tolerance is present, and form a flow in which the plating solution flows to the central portion during the plating process to improve plating processability, the second fiber web 20 may be implemented to have a density that is lower than that of each of the first fiber web 10 and the third fiber web 30 and is 0.6 g/cm³ or less, more preferably, 0.5 g/cm³ or less. In addition, in order to prevent electromagnetic waves from leaking to a lateral surface of the electromagnetic wave shielding part by exhibiting a higher level of the electromagnetic wave shielding performance, the density may be implemented to be 0.2 g/cm³ or more. In addition, in order to increase a contact area between the fibers at an interface of the first fiber web 10 and the third fiber web 30, implement a higher level of a density, and facilitate an introduction of the plating solution, the second fiber web 20 may be formed to have a large pore diameter and high porosity. To this end, a second fiber 21 forming the second fiber web 20 may have a diameter that is greater than that of each of the first fiber 11 and the third fiber 31, for example, ranging from 10 μm to 40 μm, more preferably, 15 μm to 35 μm. In addition, in order to prevent electromagnetic waves from leaking to a lateral surface by having a higher level of electromagnetic wave shielding performance and improve the plating processability, the second fiber web 20 may have a basis weight ranging from 20 g/m² to 150 g/m², more preferably, 3 g/m² to 120 g/m², a thickness ranging from 80 μm to 400 μm, more preferably, 120 μm to 300 μm, a porosity ranging from 40% to 80%, more preferably, 50% to 80%, and a mean pore diameter ranging from 30 μm to 60 μm, more preferably, 40 μm to 50 μm.

In addition, the second fiber 21 forming the second fiber web 20 may be a bicomponent fiber having a low melting point component to be attached to the first fiber web 10 and the third fiber web 30 without a separate adhesive such as a hot melt powder. The bicomponent fiber having the low melting point component may be a known fiber collectively referred to as a low melting point fiber, and a fiber cross-section may be a sheath-core type or a side-by-side type. In addition, the low melting point component may have a melting point, e.g., ranging from 80° C. to 220° C., or no melting point and a softening point of 200° C. or less. In addition, the low melting point component may be a known olefin-based or polyester-based component implemented to have a low melting point, and the present invention is not particularly limited thereto. For example, the bicomponent fiber having the low melting point component may be a sheath-core type composite fiber having a core portion of a polyethylene terephthalate support component having a melting point of about 250° C. and a sheath portion of a low melting point component, which is a modified polyethylene terephthalate having a melting point of about 120° C.

In addition, the second fiber web 20 may be manufactured by a known method of manufacturing a non-woven fabric and may be, for example, a thermal bonding non-woven fabric.

In addition, according to one embodiment of the present invention, the first fiber web 10, the second fiber web 20, and the third fiber web 30 may further satisfy a relational expression (b) of a₁≤a₃<a₂, wherein a₁, a₂, and a₃ are porosities of the first fiber web, the second fiber web, and the third fiber web, respectively, satisfy a relational expression (c) of b₁≤b₃<b₂, wherein b₁, b₂ and b₃ are mean pore diameters of the first fiber web, the second fiber web, and the third fiber web, respectively, satisfy a relational expression (d) of c₃≤c₁<c₂, wherein c₁, c₂ and c₃ are basis weights of the first fiber web, the second fiber web, and the third fiber web, respectively. This can be advantageous because it increases the density of the overall fiber web layer, improves the plating quality even at a thick thickness, and allows sufficient compressive characteristics to be exhibited when the electromagnetic wave shielding sheet is disposed in an attachment portion where a thickness tolerance is present.

In addition, the sum of the thicknesses of the first fiber web 10 and the third fiber web 30 and the thickness of the second fiber web 20 can have a thickness ratio ranging from 1:1.5 to 1:10, thereby preventing electromagnetic waves from leaking to the lateral surface while having excellent compressive characteristics, and allowing smooth plating to be performed on the central portion in the thickness direction.

In addition, the first fiber web 10, the second fiber web 20 and the third fiber web 30 may be attached by applying heat or heat and pressure and attaching one of the first fiber web 10 and the third fiber web 30 to one surface of the second fiber web 20 and then applying heat or heat and pressure and attaching the other of the first fiber web 10 and the third fiber web 30 to the other surface of the second fiber web 20. For example, the first fiber web 10 and the second fiber web 20 may be attached first, and then the third fiber web 30 may be attached to the other surface of the second fiber web 20 where the first fiber web 10 is not attached. In this case, the applied heat or the applied heat and pressure vary depending on a melting point of the low melting point component provided in the second fiber web 20, a diameter of the fiber contained in each fiber web, and basis weights and thicknesses of the fiber webs, and thus the present invention is not particularly limited thereto.

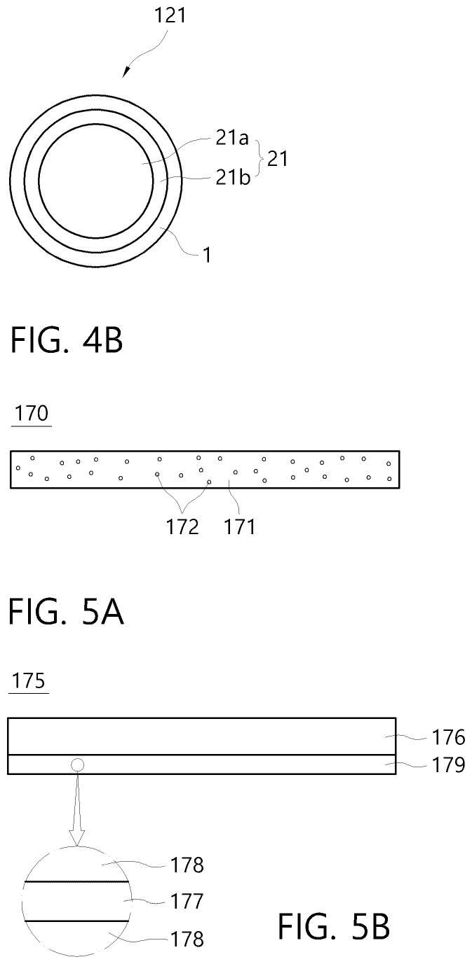

Meanwhile, according to one embodiment of the present invention, as shown in FIG. 2, in order to implement a thicker electromagnetic wave shielding part having high electromagnetic wave shielding performance and excellent plating quality, a fiber web layer 50′ may further include a fourth fiber web 40 having a density that is less than or equal to that of the second fiber web 20 between the first fiber web 10 and the second fiber web 20. Specifically, when the thickness is further increased in the structure of the fiber web layer 50 shown in FIG. 1, there is concern that plating may not be performed smoothly even when the density of the second fiber web 20 is implemented to be lower than that of each of the first fiber web 10 and the third fiber web 30. Thus, in order to implement a fiber web layer having a thicker thickness, as shown in FIG. 4, fiber webs disposed in the central portion are formed of the second fiber web 20 and the fourth fiber web 40, and a density difference is also provided therebetween to improve plating processability. When the density of the fourth fiber web 40 is lower than that of the first fiber web 10 but higher than that of the second fiber web 20, the plating quality of the fibers located in the central portion of the thickness direction may be degraded.

In addition, the fourth fiber web 40 may be implemented with a density of 0.6 g/cm³ or less, more preferably, 0.5 g/cm³ or less. In addition, in order to prevent electromagnetic waves from leaking to a lateral surface of the electromagnetic wave shielding part by exhibiting a higher level of the electromagnetic wave shielding performance, the density may be implemented to be 0.2 g/cm³ or more. In addition, in order to increase a contact area between the fibers at an interface between the first fiber web 10 and the fourth fiber web 40 and to have a large pore size and high porosity to facilitate introduction of the plating solution while the fourth fiber web 40 has a density of a higher level, a diameter of a fourth fiber 41 forming the fourth fiber web 40 may be greater than that of the first fiber 11, and may range, for example, from 10 μm to 50 μm, as another example, 15 μm to 35 μm. In addition, in order to prevent electromagnetic waves from leaking to a lateral surface by having a higher level of electromagnetic wave shielding performance and improve the plating processability, the second fiber web 20 may have a basis weight ranging from 20 g/m² to 200 g/m², as another example, 20 g/m² to 150 g/m² or 30 g/m² to 120 g/m², a thickness ranging from 80 μm to 600 μm, as another example, 80 μm to 400 μm or 120 μm to 300 μm, a porosity ranging from 40% to 80%, as another example, 50% to 70%, and a mean pore diameter ranging from 30 μm to 80 μm, as another example, 30 μm to 60 μm or 40 μm to 50 μm.

In addition, the fourth fiber web 40 may be within the basis weight, porosity, thickness, and density ranges described for the second fiber web 20. For plating the entire region in the thickness direction of the fiber web layer while achieving high-performance electromagnetic wave shielding, the first fiber web 10, the second fiber web 20, the third fiber web 30, and the fourth fiber web 40 satisfy a relational expression (e) a₁≤a₃<a₂≤a₄, wherein a₁, a₂, a₃, and a₄ are porosities of the first fiber web, the second fiber web, the third fiber web, and the fourth fiber web, respectively, a relational expression (f) b₁≤b₃<b₂≤b₄, wherein b₁, b₂, b₃, and b₄ are mean pore diameters of the first fiber web, the second fiber web, the third fiber web, and the fourth fiber web, respectively, and a relational expression (g) c₃≤c₁≤c₄≤c₂, wherein c₁, c₂, c₃, and c₄ are basis weights of the first fiber web, the second fiber web, the third fiber web, and the fourth fiber web, respectively. When any one of the relational expressions (e) to (g) is not satisfied, it may be difficult to achieve the desired effect.

In addition, the fourth fiber web 40 may be attached to the first fiber web 10 and the second fiber web 20 through heat. To this end, the fourth fiber web 40 may be a bicomponent fiber containing a low melting point component. A description of the bicomponent fiber is the same as the description of the second fiber web 20, and thus a detailed description thereof will be omitted.

In addition, the fourth fiber web 40 may be manufactured by a known method of manufacturing a non-woven fabric and may be, for example, a thermal bonding non-woven fabric.

In addition, when the fourth fiber web 40 is further included, the first fiber web 10 and the fourth fiber web 40, and the second fiber web 20 and the third fiber web 30 may be attached by applying heat or heat and pressure, and then the second fiber web 20 and the fourth fiber web 40 may be attached by applying heat or heat and pressure, thereby manufacturing the fiber web layer 50′. In this case, the applied heat or the applied heat and pressure vary depending on melting points of the low melting point components provided in the second fiber web 20 and the fourth fiber web 40, a diameter of the fiber contained in each fiber web, and basis weights and thicknesses of the fiber webs, and thus the present invention is not particularly limited thereto.

Next, a process of integrally forming a metal layer on outer surfaces of the first fiber 11, the second fiber 21, the third fiber 31, and the fourth fiber 41, which are included in the fiber web layers 50 and 50′, by electroless plating the manufactured fiber web layers 50 and 50′ is performed.

The electroless plating may be performed on the fiber web layers 50 and 50′ according to known methods and conditions. For example, the electroless plating may be performed by including operation 1-1) of immersing the fiber web layers 50 and 50′ in a catalyst solution to perform a catalytic treatment, operation 1-2) of activating the catalytically treated fiber web layers 50 and 50′, and operation 1-3) of electroless plating the activated fiber web layers 50 and 50′ to form a metal layer. In this case, the electroless plating may be performed by further including degreasing or hydrophilizing the fiber web layers 50 and 50′ before performing operation 1-1).

The degreasing is an operation of washing away oxides or foreign materials, especially oil and grease, present on surfaces of the fiber web layers 50 and 50′ by treating the oxides or foreign materials with an acid or alkaline surfactant. When foreign materials are present on the surfaces of the fiber web layers 50 and 50′, the catalyst or a chemical reaction during the activating may be inhibited due to the foreign materials or a void phenomenon and therefore the metal layer plating may not be formed uniformly, and even when the plating is performed, a bonding force between the plated surface and the metal layer may be very poor, which may significantly degrade product reliability. However, when the acid or alkaline surfactant used in the degreasing is not completely washed off, it may act as a contaminant for a subsequent treatment solution (a catalyst solution or activation solution), and therefore the surfactant should be sufficiently washed off at an appropriate temperature and pressure.

When materials of fiber web layers 50 and 50′ are hydrophobic, the hydrophilizing is an operation of converting the hydrophobic materials of the fiber web layers 50 and 50′ to hydrophilic materials, simultaneously introducing functional groups such as carboxyl groups, amine groups, and hydroxyl groups to the surfaces of the fiber web layers 50 and 50′ to facilitate adsorption of metal ions and form fine cavities on the surfaces of fiber web layers 50 and 50′, and increasing surface roughness to improve adhesive strength between the precipitated metal layer and the surfaces of the fiber web layers 50 and 50′. The hydrophilizing may be performed by mixing an alkali metal hydroxide or a nitrogen compound with a surfactant, and sodium hydroxide (NaOH) or potassium hydroxide (KOH) may be used as the hydroxide, and the nitrogen compound may include an ammonium salt or an amine compound. An ammonium salt substituted with an alkyl group or aryl group, for example, such as ammonium hydroxide, ammonium chloride, ammonium sulfate, ammonium carbonate or triethylammonium salt, tetraethylammonium salt, trimethylammonium salt, tetramethylammonium salt, trifluoro ammonium salt, or tetrafluoro ammonium salt may be used as the ammonium salt, and an aliphatic amine compound, for example, such as methylamine, ethylamine, dimethylamine, diethylamine, trimethylamine, ethylenediamine, diethylenetriamine, or a urea and hydrazine derivative may be used as the amine compound. As the surfactant, an anionic surfactant, a cationic surfactant, or a neutral surfactant, such as sodium alkyl sulfonate (SAS), sodium alkyl sulfate ester (AS), sodium olefin sulfonate (AOS), or alkyl bezene sulfonate (LAS) may be used. In this case, the hydrophilizing may be performed by immersing the fiber web layers 50 and 50′ in a hydrophilization solution containing the compounds at a temperature ranging 20° C. to 100° C. for about 2 to 20 minutes.

Operation 1-1) is an operation of performing catalyzing treatment to facilitate plating by precipitating catalyst particles on the surfaces of fiber web layers 50 and 50′ undergoing the degreasing and hydrophilizing.

The catalyst solution contains one or more compounds selected from the group consisting of salts of Ti, Sn, Au, Pt, Pd, Ni, Cu, Ag, Al, Zn, and Fe, and the catalyst solution may contain a colloidal solution consisting of salts of Ti, Sn, Au, Pt, Pd, Ni, Cu, Ag, Al, Zn and Fe, or a noble metal complex ion. For example, a solution containing 50 to 250 ml of hydrochloric acid, 50 to 300 g of sodium chloride or potassium chloride, 5 to 60 g of tin chloride (SnCl₂), and 0.1 to 5 g of palladium chloride (PdCl₂) per liter of ultrapure water may be used as the colloidal solution.

In this case, in order to improve adsorption efficiency of the catalyst particles before performing operation 1-1), a pre-dip process may be performed as a preliminary catalyst treatment process, and the pre-dip process may prevent the catalyst solution used in the catalyst treatment from being contaminated or changed in its concentration by immersing the fiber web layers 50 and 50′ in a low-temperature catalyst solution prior to the catalyzing treatment.

Next, operation 1-2) of activating the catalyst-treated fiber web layers 50 and 50′ is performed. The activating is an operation of improving activity of the adsorbed metal particles and a precipitation behavior of the electroless plating solution after the catalyzing. Through the activating, the metal particles surrounding the colloidal particles are removed to leave only the adsorbed catalyst, thereby facilitating the precipitation of the metal layer through the electroless plating. For example, the activating process may be an operation of immersing the fiber web layers 50 and 50′ in a mixed solution of distilled water and sulfuric acid for 30 seconds to 5 minutes.

Next, operation 1-3) of forming the metal layer on the activated fiber web layers 50 and 50′ through electroless plating is performed. The electroless plating may generally be divided into a reduction plating method and a displacement plating method. The reduction plating method is a method in which a metal is precipitated through a reduction reaction and plated on a surface of a substrate, and the displacement plating method is a method in which a metal with a relatively high reduction power is precipitated and plated due to a difference in a reduction power of the metal. For example, the displacement plating method may be used in operation 1-3).

The displacement plating method is a plating method of immersing the fiber web layers 50 and 50′ in a primary plating solution having a relatively low reduction power and then immersing the fiber web layers 50 and 50′ in a secondary plating solution having a relatively high reduction power to precipitate the metal of the secondary plating solution. The above primary and secondary plating solutions may each contain a metal selected from the group consisting of Ti, Sn, Au, Pt, Pd, Ni, Cu, Ag, Al, Zn, and Fe,, preferably, the primary plating solution may contain Ni ions, and the secondary plating solution may contain Cu ions. The displacement plating method may ultimately form the metal layer by immersing the fiber web layers 50 and 50′ at a temperature ranging from 30 to 70° C. for 1 to 10 minutes.

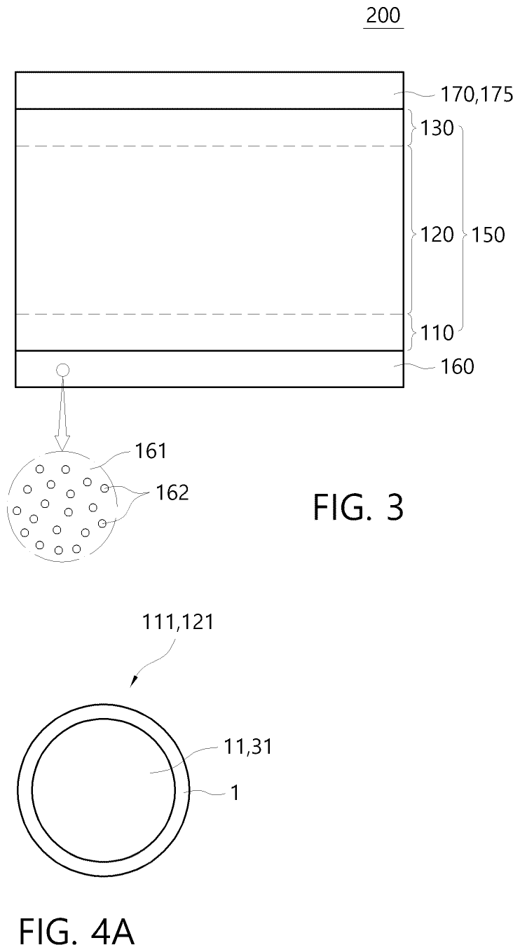

Referring to FIGS. 3, 4A, and 4B, even when the fiber web layers 50 and 50′ have a thick thickness, an electromagnetic wave shielding part 150 may be manufactured to have a web shape of a three-dimensional network structure due to metal-coated fibers 111, 121, and 131 in which the metal layer 1 is integrally formed on the fibers 11, 21, and 31 disposed in the entire region in the thickness direction by adjusting densities of several fiber webs and stacking the several fiber webs.

Next, as operation (2) according to the present invention, an operation of laminating a first conductive adhesive member on one surface of the electroless-plated first fiber web 10 of the electromagnetic wave shielding part 150 and laminating a second member on one surface of the electroless-plated third fiber web 30 is performed.

With reference to FIG. 3, the first conductive adhesive member 160 serves to fix an electromagnetic wave shielding sheet 200 on an adherend surface and is implemented to have electrical and thermal conductivity in order to improve electromagnetic wave shielding and heat transfer characteristics. The first conductive adhesive member 160 includes an adhesive component 161 and conductive fillers 162. Any known adhesive component may be used as the adhesive component 161 without limitation and may be, for example, a mixture of one or more of an acrylic-based resin, a silicone-based resin, etc. In addition, the conductive filler 162 may be one or more selected from the group consisting of nickel, nickel-graphite, carbon black, graphite, aluminum, copper, and silver. In addition, the first conductive adhesive member 160 may contain the conductive fillers 162 in an amount of 5 to 50 wt %, and more preferably, 5 to 20 wt %, based on 100 wt % of the first conductive adhesive member 160. In addition, the conductive filler 162 may have an average particle diameter ranging from 1 μm to 5 μm, but the present invention is not limited thereto.

The first conductive adhesive member 160 may be disposed on the plated first fiber web 10 among both surfaces of the electromagnetic wave shielding part 150, i.e., one surface of the first web part 110, and then pressurized to be attached. In this case, some regions of the first conductive adhesive member 160 may infiltrate through open pores on the surface of the first web part 110 so that the first conductive adhesive member 160 may be positioned inside the first web part 110 at a predetermined thickness. In addition, when curing all or a portion of the adhesive resin is required when pressurized, heat may be applied together with a pressure or after the pressure is applied. The applied pressure may be appropriately selected in consideration of the thickness, porosity, pore diameter, and flowability of the conductive adhesive member of the first web part 110, and the applied heat may also be appropriately selected in consideration of the composition of the conductive adhesive member, and therefore the present invention is not particularly limited thereto.

In addition, the first conductive adhesive member 160 may be directly applied onto one surface of the first web part 110 in an undried composition state, or alternatively, the first conductive adhesive member 160 may be separately laminated onto one surface of the first web part 110 in a dried state to have a predetermined thickness on a release film.

In the case in which the first conductive adhesive member 160 is in an undried composition state, in addition to the adhesive component 161 and the conductive fillers 162, additives such as a solvent, a dispersant, and other known leveling agents, plasticizers, ultraviolet blockers, antioxidants, and antistatic agents may be further contained.

In addition, the thickness of the first conductive adhesive member 160 may be changed depending on the purpose, and thus the present invention is not particularly limited thereto. For example, the first conductive adhesive member 160 may be formed with a thickness ranging from 5 μm to 25 μm.

In addition, a second member is laminated on one surface of the electromagnetic wave shielding part 150 of the electroless-plated third fiber web 30, that is, on the third web part 130.

The second member may be provided with an adhesive member, a second conductive adhesive member 170, or a cover member 175 according to the use of the electromagnetic wave shielding sheet 200. That is, when the second member is attached to an adherend surface with no electrical conductivity, an adhesive member may be disposed, and when the second member is attached to an adherend surface with electrical conductivity, the second conductive adhesive member 170 may be disposed to increase electromagnetic shielding and vertical thermal conductivity. Additionally, when the second member is not attached to the adherend surface, the cover member 175 for protecting an exposed surface of the electromagnetic wave shielding part 150 may be disposed.

Describing the case in which the second member is the adhesive member or the second conductive adhesive member 170 with reference to FIG. 5A, the second member may include an adhesive component 171 to have adhesive characteristics for attachment to an adherend surface. In addition, in the case of the conductive adhesive member 170, the second member may further include conductive fillers 172 dispersed in the adhesive component 171. Descriptions of the adhesive component 171, the conductive filler 172, and the conductive adhesive member are the same as the description of the first conductive adhesive member, and thus detailed descriptions thereof will be omitted.

Meanwhile, when the second component is the adhesive member or the second conductive adhesive member 170, unlike the first conductive adhesive member 160, the adhesive component 171 may have material-selective adhesive characteristics of not adhering to an adherend surface made of a specific material due to lack of or low adhesive strength, but adhering to adherend surfaces made of other materials. This may be advantageous in improving workability because, when disposed on a predetermined adhesion surface, the electromagnetic wave shielding sheet 200 has low adhesive characteristics on a surface of a pickup jig and is therefore easily separated, but has excellent adhesive strength to an adherend surface and is therefore prevented from being delaminated after attachment. The material-selective adhesive characteristics may be designed to have low or close to zero adhesive strength according to a type of a specific material, and a known adhesive resin may be used for this purpose, and thus the present invention is not particularly limited thereto. For example, the cover member with the material-selective adhesive characteristics may be a cured epoxy resin or a cured acrylic resin with low or no adhesive characteristics on a urethane-based adherend surface.

Alternatively, the second member, which is the adhesive member or the second conductive adhesive member 170, may be formed to have a lower adhesive strength than the first conductive adhesive member 160. Preferably, the adhesive member or the second conductive adhesive member 170 may have adhesive strength of 20% or less of the adhesive strength of the first conductive adhesive member 160 measured using KS T 1028, which may be advantageous in further improving reworkability and pick-up processability. In this case, as an example, the adhesive strength of the first conductive adhesive member 160 may be implemented at a level ranging from 1000 gf to 12000 gf, and the adhesive strength of the second member, which is the adhesive member or the conductive adhesive member 170, may be implemented at a range of 100 gf to 200 gf.

In addition, the second member may be a cover member 175 that performs a function of protecting the surface of the third web part 130 of the electromagnetic wave shielding part 150 from an external physical and chemical environment. Referring to FIG. 5B, when the second member is the cover member 175, the cover member 175 may include a protective film 176 and an adhesive layer 179 for fixing the protective film 176 to the electromagnetic wave shielding part 150. The protective film 176 may be a known film used as a protective film, such as polyester or polyimide, and the present invention is not particularly limited thereto. In addition, the adhesive layer 179 may be a single layer made of an adhesive resin or a double-sided tape with adhesives 178 provided on both surfaces of a substrate 177 as shown in FIG. 5B.

The thickness of the second member may be changed depending on the purpose, and thus the present invention is not particularly limited thereto. For example, when the second member is the second conductive adhesive member 170, the second conductive adhesive member 170 may be formed to have a thickness ranging from 10 μm to 30 μm.

The electromagnetic wave shielding sheet 200 implemented through the above-described manufacturing method is formed of the metal-coated fibers 111, 121, and 131 in which the metal layer 1 surrounds the fibers 11, 21, and 31, has a web shape of a three-dimensional network structure in which the metal layer 1 is integrally formed in the entire region in the thickness direction, and includes the electromagnetic wave shielding part 150 having a thickness of 100 μm or more, preferably, ranging from 100 μm to 300 μm, and in which the first web part 110, the second web part 120, and the third web part 130 satisfying a relational expression (A) D₂<D₃≤D₁ (wherein D₁, D₂, and D₃ are the densities of the first web part 110, the second web part 120, and the third web part 130, respectively) are sequentially included in the thickness direction, the first conductive adhesive member 160 disposed on one surface of the first web part 110 of the electromagnetic wave shielding part 150, and the second member disposed on one surface of the third web part 130 of the electromagnetic wave shielding part 150.

To describe the manufactured electromagnetic wave shielding sheet by focusing on content not described in the method of manufacturing electromagnetic wave shielding sheet, the electromagnetic wave shielding part 150 has a web shape of a three-dimensional network structure formed of the metal-coated fibers 111, 121, and 131 in which the metal layer 1 surrounding the fibers 11, 21, and 31 is integrally formed in the entire region in the thickness direction.

When several conductive fiber webs coated with metals on fibers are stacked, since the metals are not integrally contained in the conductive fiber webs, the metals contained in the conductive fiber webs should be electrically connected. However, since contact resistance is present at an interface while the metal-coated fibers are in contact with each other, there may be a limit to reducing vertical resistance. In addition, in order to reduce the contact resistance, the conductive fiber webs should be attached. However, an adhesive component such as a hot melt powder used for attachment has high resistance, and thus there is concern that electromagnetic waves may leak toward the lateral surface of the electromagnetic wave shielding part along a side where the adhesive component is present. In addition, there is a risk of pore blockage due to the adhesive component, and in this case, it is difficult to maintain the three-dimensional network structure and thus flexibility may be degraded.

However, in the electromagnetic wave shielding sheet 200 according to the present invention, even in the case of the electromagnetic wave shielding part 150 having a thick thickness of 100 μm or more, the metal layer 1 located throughout the entire region in the thickness direction is formed integrally through electroless plating so that there is no contact resistance at the interface, and thus lower vertical resistance characteristics can be implemented. In addition, since there are no other components, such as adhesive resins, other than the metal layer 1 exposed to the outside, electromagnetic waves may be prevented from leaking to the lateral surface, ultimately implementing high vertical and horizontal shielding performance. In addition, the excellent three-dimensional network structure maintained even after the plating may provide an adhering force and flexibility to an adherend surface with a curvature or step difference.

In addition, since the electromagnetic wave shielding part 150 is implemented by laminating three or more types of fiber webs with different densities and integrally plating the fiber webs, the first web part 110, the second web part 120, and the third web part 130 satisfying the relational expression (A) D₂<D₃≤D₁ (wherein D₁, D₂, and D₃ are the densities of the first web part 110, the second web part 120, and the third web part 130, respectively) are sequentially included in the thickness direction. Here, the first web part 110 and the third web part 130 are implemented to have high densities as described above for the fiber webs and are parts that exhibit a high-performance electromagnetic wave shielding function and a vertical electromagnetic wave shielding function, and the second web part 120 has electromagnetic wave shielding performance to the extent that at least no electromagnetic waves leak to the lateral surface and may exhibit compression characteristics considering a thickness tolerance of a mounting portion. In other words, the electromagnetic wave shielding part 150 being implemented to satisfy the relational expression (A) means that the metal layer 1 is integrally formed on the outer surfaces of the fibers 11, 21, and 31 located in the entire region in the thickness direction of the electromagnetic wave shielding part 150. In addition, the metal-coated fiber 121 in the second web part 120 may have a larger diameter than the metal-coated fibers 111 and 131 located in the first web part 110 and the third web part 130, which may be advantageous in achieving the objective of the present invention.

In addition, as described above, when the fourth fiber web 40 is included in the fiber web layer 50′ before the plating, the electromagnetic wave shielding part may include a fourth web part with a density less than or equal to that of the second web part 120 between the first web part 110 and the second web part 120. Even in this case, the metal layer 1 may be integrally formed on the outer surfaces of the fibers 11, 21, 31, and 41 located in the entire region in the thickness direction of the electromagnetic wave shielding part 150. In addition, the metal-coated fiber in the fourth web part may have a larger diameter than the metal-coated fibers 111 and 121 located in the first web part 110 and the second web part 120, which may be advantageous in achieving the objective of the present invention.

Meanwhile, according to one embodiment of the present invention, some regions of the first web part 110 and the second web part 120 of the electromagnetic wave shielding part 150 may be in a punched state, and in this case, the third web part 130 may be punched or not punched in regions corresponding to the punched regions. When the fiber web layer 50 is manufactured prior to manufacturing the electromagnetic wave shielding part, the partially punched electromagnetic wave shielding part may be manufactured such that the first fiber web 10 and the second fiber web 20 are laminated and then punched, and the third fiber web 30 is laminated to manufacture a partially punched fiber web layer and then electroless-plated.

In addition, a conventional metal material may be used as the metal layer 1 without limitation, may be a metal material that can be formed through plating, and as an example, may be one or more metal materials selected from the group consisting of aluminum, nickel, copper, silver, gold, chromium, platinum, a titanium alloy, and stainless steel. For example, the metal layer 1 may include nickel and/or copper, and specifically, may be formed of three layers of a nickel layer/a copper layer/a nickel layer. In this case, the copper layer has low electrical resistance and therefore exhibits excellent electromagnetic wave shielding performance and may minimize cracks of the metal layer 1 even due to deformation such as wrinkling or stretching and improve elasticity characteristics. In addition, the nickel layer formed on the copper layer may prevent the electromagnetic wave shielding performance from being degraded by preventing oxidation of the copper layer.

In addition, the metal layer 1 may have a thickness, for example, ranging from 0.1 μm to 2 μm, and when a thickness of the metal layer 1 exceeds 2 μm, cracks and delamination may be likely to occur when the shape is deformed, and when the thickness is less than 0.1 μm, it may be difficult to exhibit the electromagnetic wave shielding performance at a desired level.

In addition, in the electromagnetic wave shielding sheet 200, the electromagnetic wave shielding part may be formed to have a thickness of 100 μm or more or, as another example, ranging from 100 μm to 300 μm.

Although exemplary embodiments of the present invention have been described, the spirit of the present invention is not limited to the exemplary embodiments disclosed herein, and it should be understood that numerous other embodiments can be devised by those skilled in the art that will fall within the same spirit and scope of the present invention through addition, modification, deletion, supplement, and the like of a component, and also these other embodiments will fall within the spirit and scope of the present invention.

What is claimed is:

1. A method of manufacturing an electromagnetic wave shielding sheet, comprising:
operation 1) of manufacturing an electromagnetic wave shielding part at least having a thickness of 100 μm by electroless plating a fiber web layer where a first fiber web, a second fiber web, and a third fiber web satisfying a relational expression a) d₂<d₃≤d₁ are sequentially laminated, wherein d₁, d₂, and d₃ are densities of the first fiber web, the second fiber web, and the third fiber web, respectively; and an electroless-plated first fiber web and an electroless-plated third fiber web are obtained; and
operation 2) of laminating a first conductive adhesive member on one surface of the electroless-plated first fiber web of the electromagnetic wave shielding part and laminating a second member on one surface of the electroless-plated third fiber web of the electromagnetic wave shielding part.

2. The method according to claim 1, wherein
the second fiber web comprises a bicomponent fiber having a low melting point component; and
the fiber web layer is manufactured by attaching a first one of the first fiber web and the third fiber web to a first surface of the second fiber web through heat and attaching a second one of the first fiber web and the third fiber web to a second surface of the second fiber web through heat.

3. The method according to claim 1, wherein the first fiber web, the second fiber web, and the third fiber web are formed of a first fiber, a second fiber, and a third fiber, respectively, and a diameter of the second fiber is greater than a diameter of each of the first fiber and the third fiber.

4. The method according to claim 1, wherein a ratio of a sum of thicknesses of the first fiber web and the third fiber web to a thickness of the second fiber web ranges from 1:1.5 to 1:10.

5. The method according to claim 1, wherein a density of the first fiber web ranges from 0.6 g/m³ to 2.0 g/m³, and a density of the third fiber web is at least 0.6 g/m³.

6. The method according to claim 1, wherein the first fiber web, the second fiber web, and the third fiber web satisfy relational expressions b) to d) according to the following conditions:
the relational expression b) is a₁≤a₃<a₂, wherein a₁, a₂, and a₃ are porosities of the first fiber web, the second fiber web, and the third fiber web, respectively;
the relational expression c) is b₁≤b₃<b₂, wherein b₁, b₂, and b₃ are mean pore diameters of the first fiber web, the second fiber web, and the third fiber web, respectively; and
the relational expression d) is c₃≤c₁<c₂, wherein c₁, c₂, and c₃ are basis weights of the first fiber web, the second fiber web, and the third fiber web, respectively.

7. The method according to claim 1, wherein the fiber web layer further comprises a fourth fiber web having a density, wherein the density is less than or equal to a density of the second fiber web between the first fiber web and the second fiber web.

8. The method according to claim 7, wherein
each of the second fiber web and the fourth fiber web comprises a bicomponent fiber containing a low melting point component; and
the fiber web layer is manufactured by attaching the first fiber web to one surface of the fourth fiber web through heat, attaching the third fiber web to one surface of the second fiber web through heat, and attaching the second fiber web and the fourth fiber web through heat.

9. The method according to claim 7, wherein the first fiber web and the fourth fiber web are formed of a first fiber and a fourth fiber, respectively, and a diameter of the fourth fiber is greater than a diameter of the first fiber.

10. The method according to claim 7, wherein the first fiber web, the second fiber web, and the third fiber web satisfy relational expressions e) to g) according to the following conditions:
the relational expression e) is a₁≤a₃<a₂≤a₄, wherein a₁, a₂, a₃, and a₄ are porosities of the first fiber web, the second fiber web, the third fiber web, and the fourth fiber web, respectively;
the relational expression f) is b₁≤b₃<b₂≤b₄, wherein b₁, b₂, b₃, and b₄ are mean pore diameters of the first fiber web, the second fiber web, the third fiber web, and the fourth fiber web, respectively; and
the relational expression g) is c₃≤c₁<c₄≤c₂, wherein c₁, c₂, c₃, and c₄ are basis weights of the first fiber web, the second fiber web, the third fiber web, and the fourth fiber web, respectively.

11. An electromagnetic wave shielding sheet, comprising
an electromagnetic wave shielding part, wherein the electromagnetic wave shielding part is formed of a metal-coated fiber wherein a metal layer surrounds a fiber, the metal layer has a web shape of a three-dimensional network structure integrally formed in an entire region in a thickness direction, a first web part, a second web part, and a third web part satisfying a relational expression a) D₂<D₃≤D₁ are sequentially comprised in the thickness direction, and the electromagnetic wave shielding part at least has a thickness of 100 μm, or wherein D₁, D₂, and D₃ are densities of the first web part, the second web part, and the third web part, respectively;
a first conductive adhesive member disposed on one surface of the first web part of the electromagnetic wave shielding part; and
a second member disposed on one surface of the third web part of the electromagnetic wave shielding part.

12. The electromagnetic wave shielding sheet according to claim 11, wherein the metal layer is formed of at least one metal material selected from the group consisting of aluminum, nickel, copper, silver, gold, chromium, platinum, a titanium alloy, and stainless steel.

13. The electromagnetic wave shielding sheet according to claim 11, wherein the metal-coated fiber in the second web part has a larger diameter than the metal-coated fibers located in the first web part and the third web part.

14. The electromagnetic wave shielding sheet according to claim 11, wherein the electromagnetic wave shielding part further comprises a fourth web part where a metal-coated fiber having a larger diameter than the metal-coated fibers located in the first web part and the second web part is disposed between the first web part and the second web part.

15. The electromagnetic wave shielding sheet according to claim 11, wherein the first conductive adhesive member contains an adhesive component and conductive fillers dispersed in the adhesive component and occupying 5 to 20 wt % based on a total weight of the first conductive adhesive member.

16. The electromagnetic wave shielding sheet according to of claim 11, wherein the second member comprises an adhesive member, a second conductive adhesive member, or a cover member.

17. The electromagnetic wave shielding sheet according to claim 11, wherein the second member is a second conductive adhesive member, and the second conductive adhesive member has adhesive strength of 20% or less of an adhesive strength of the first conductive adhesive member measured according to KS T 1028.

18. An electronic device comprising the electromagnetic wave shielding sheet according to claim 11.
